(19) United States
(12) Patent Application Publication
(10) Pub. No.: US 2022/0216328 A1
(43) Pub. Date: Jul. 7, 2022

(54) GATE-TO-CONTACT SHORT PREVENTION WITH AN INNER SPACER

(71) Applicant: QUALCOMM Incorporated, San Diego, CA (US)

(72) Inventors: Youseok SUH, San Diego, CA (US); Hyunwoo PARK, San Diego, CA (US); Youn Sung CHOI, San Diego, CA (US); Kwanyong LIM, San Diego, CA (US)

(21) Appl. No.: 17/141,016

(22) Filed: Jan. 4, 2021

(51) Int. Cl. H01L 29/66; H01L 29/78; H01L 21/8234

(52) U.S. Cl. CPC H01L 29/66795; H01L 29/7851; H01L 21/823468; H01L 21/823431; H01L 21/823418; H01L 29/6656

(57) ABSTRACT

Certain aspects of the present disclosure generally relate to a self-aligned contact with gate-to-contact short prevention in a multi-gate transistor structure, such as a multi-gate fin field-effect transistor (finFET) structure. An example multi-gate transistor structure includes a semiconductor fin, a first gate, a first spacer, a source or drain contact, and a first nonconductive liner. The first gate is disposed above and partially surrounds a portion of the semiconductor fin. The first spacer is located adjacent to a side of the first gate. The source or drain contact is coupled to a source or drain region of the semiconductor fin. The first nonconductive liner is disposed between the source or drain contact and the first spacer.

### BACKGROUND

### Field of the Disclosure

Certain aspects of the present disclosure generally relate to electronic components and, more particularly, to techniques and apparatus for preventing shorting in a transistor between a gate and a source or drain contact with an inner spacer liner.

### Description of Related Art

A continued emphasis in semiconductor technology is to create improved performance semiconductor devices at competitive prices. This emphasis over the years has resulted in extreme miniaturization of semiconductor devices, made possible by continued advances in semiconductor processes and materials in combination with new and sophisticated device designs. Large numbers of transistors are employed in integrated circuits (ICs) in many electronic devices. For example, components such as central processing units (CPUs), graphics processing units (GPUs), and memory systems each employ a large quantity of transistors for logic circuits and memory devices.

Alternative transistor designs to planar transistors have been developed to address various issues with the planar transistor, such as short channel effects as channel lengths in transistors are scaled down. For example, a fin field-effect transistor (FET) (finFET) has been developed that provides a conducting channel wrapped by a thin silicon “fin,” which forms the gate of the device. FinFET devices may provide faster switching times and higher current densities than planar transistor technology. Gate-all-around (GAA) field-effect transistors (FETs) have enabled a reduction of transistor node sizes below 10 nm. In certain cases, GAA FETs have nanowires, which form the channels, embedded in a gate material disposed between the source and drain. GAA FETs can be designed to have a lower threshold voltage than similar finFET devices, because GAA FETs have better short channel control. This allows a reduction in supply voltage, which results in a quadratic reduction in power consumption because of voltage scaling.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description” one will understand how the features of this disclosure provide advantages that include desirable transistor yields in semiconductor devices due to an extension of the gate-to-contact electrical isolation.

Certain aspects of the present disclosure provide a fin field-effect transistor (finFET) structure. The finFET structure generally includes a semiconductor fin, a first gate, a first spacer, a source or drain contact, and a first nonconductive liner. The first gate is disposed above and partially surrounds a portion of the semiconductor fin. The first spacer is located adjacent to a side of the first gate. The source or drain contact is coupled to a source or drain region of the semiconductor fin. The first nonconductive liner is disposed between the source or drain contact and the first spacer.

Certain aspects of the present disclosure generally relate to a method of fabricating a finFET structure. The method generally includes forming a first nonconductive liner adjacent to a first spacer, the first spacer being located adjacent to a side of a first gate, wherein the first gate is disposed above and partially surrounds a portion of a semiconductor fin. The method further includes forming a source or drain contact above a source or drain region of the semiconductor fin, such that the first nonconductive liner is disposed between the source or drain contact and the first spacer.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1 is a cross-sectional view illustrating an example semiconductor device, in accordance with certain aspects of the present disclosure.

FIG. 2A is an isometric view illustrating a fin field-effect transistor (finFET) structure having a nonconductive liner to prevent or reduce electrical shorting between a metal gate and a self-aligned contact (SAC), in accordance with certain aspects of the present disclosure.

FIG. 2B is a cross-sectional view illustrating certain portions of the finFET structure of FIG. 2A, in accordance with certain aspects of the present disclosure.

FIGS. 3A-3G are cross-sectional views illustrating example operations for fabricating a finFET structure using spacer liners on sidewalls of the gates, in accordance with certain aspects of the present disclosure.

FIGS. 4A-4F are cross-sectional views illustrating example operations for fabricating a finFET structure with a hard mask above the gates and an inner spacer liner, in accordance with certain aspects of the present disclosure.

FIG. 5 is a flow diagram illustrating example operations for fabricating a finFET structure, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure relate to a multi-gate transistor structure and a method of fabricating a multi-gate transistor structure to prevent a gate-to-contact short with an inner spacer liner (also referred to as a “contact liner”).

As an alternative to planar transistors, certain semiconductor devices employ additional dimensions of coupling between the gate and channel regions of a transistor to obtain node sizes below 10 nanometers, such as a fin field-effect transistor (finFET) and a gate-all-around (GAA) transistor. These non-planar transistors may be referred to as multi-gate transistors or three-dimensional (3D) transistors. As node sizes are scaled below 10 nm (e.g., 5, 6, or 7 nm), a dielectric spacer between a gate and a source/drain contact may, in some cases, be too thin or non-existent to prevent a gate-to-contact short, due to etch erosion of the dielectric spacer during the source/drain contact formation. For example, the gate-to-contact short may occur at the top of the gate where a tapered contact to the source/drain is proximate to a gate due to a decrease in the contact poly pitch. With gate chamfering processes, contact poly pitch reduction decreases the post-replacement metal gate (RMG) and contact process margin significantly. In turn, the frequency and overall likelihood of gate-to-contact shorts may increase. The gate-to-contact short may render certain transistors inoperable due to the short between the gate and source/drain regions, and in certain cases, the gate-to-contact short may be a yield detractor in certain node sizes below 10 nm.

Under certain finFET fabrication methods during gate chamfering processes (e.g., post-RMG), a self-aligned contact (SAC) silicon nitride height may be generally increased to compensate for erosion during contact etching steps. Such an increase in height of the silicon nitride may mitigate some shorting between the gate and contact. However, due to the height of the silicon nitride, the height of the contact may also increase substantially, which may make it difficult to form conformal inner spacers between the contacts and the gates to separate the contact metal from the gate. Gate chamfering processes generally see a limit in gate height reduction due to intrinsic etching back processes regarding within-wafer uniformity, especially when compared to gate chemical mechanical planarization (CMP) processes. Increasing SAC silicon nitride height generally improves contact process margins and helps prevent gate-to-contact shorts. However, the increase in SAC silicon nitride height may cause the contact process window to be significantly narrower, which may make it more difficult to ensure there is in fact no gate-to-contact short.

Certain aspects of the present disclosure provide multi-gate transistors (such as finFETs or GAA FETs) with an inner spacer liner (also referred to herein as a “nonconductive liner”) between the gate and source/drain contact to prevent or reduce shorting or capacitive coupling between the gate and source/drain contact. In certain aspects, an inner spacer liner may be formed along the walls of the cavities in which the contacts are formed. The inner spacer liner may enable the formation of additional dielectric material (in addition to a gate spacer) between the gate and source/drain contact to prevent shorting and/or reduce the capacitive coupling between the gate and source/drain contact. In certain aspects, the inner spacer liner may extend the gate spacers that enable the formation of SACs coupled to the source and drain. In certain aspects, a hard mask may be formed on top of the SAC dielectric in order to prevent or decrease erosion of the gate spacers during the contact etching process and further mitigate shorting and/or capacitive coupling between the gate and the SACs.

The inner spacer liner and SAC techniques described herein may enable a reduction of the SAC height, which may be beneficial to forming conformal inner spacers adjacent to the contact to separate the contact metal from the gate. The inner spacer liner and SAC techniques described herein may provide a desirable SAC process margin and mitigate the gate-to-contact shorts, which may provide desirable transistor yields, especially for node sizes below 10 nm.

### Example Semiconductor Device

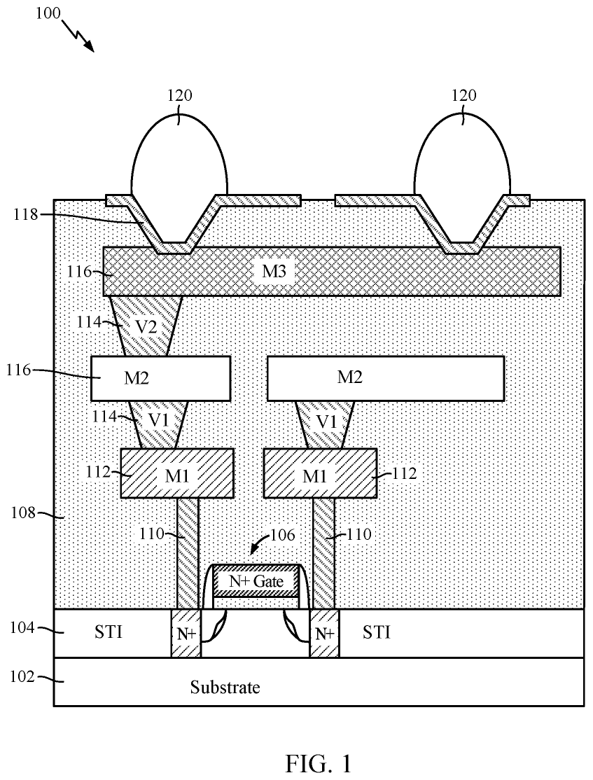

FIG. 1 is a cross-sectional view of an example semiconductor device 100, in which certain aspects of the present disclosure may be practiced. As shown, the semiconductor device 100 may include a substrate 102, a dielectric region 104, an active electrical device 106 (e.g., a transistor), dielectric layers 108, local conductive contacts 110 (e.g., source/drain conductive contacts, which are often abbreviated as CA), and a first layer of conductive traces 112 (e.g., metal layer one—M1). In certain aspects, the semiconductor device 100 may include layers of conductive vias 114 (e.g., via layer one-V1, and via layer two—V2), additional layers of conductive traces 116 (e.g., metal layer two—M2, and metal layer three—M3), under-bump conductive pads 118, and solder bumps 120.

The substrate 102 may be, for example, a portion of a semiconductor wafer, such as a wafer of silicon (Si), silicon carbide (SiC), sapphire, diamond, or other suitable substrate materials. The dielectric region 104 may be disposed above the substrate 102. The dielectric region 104 may comprise an oxide, such as silicon dioxide (SiO₂). In aspects, the dielectric region 104 may be a shallow trench isolation (STI) region configured to electrically isolate the active electrical device 106 from other electrical components arranged above the substrate 102.

The active electrical device 106 may be disposed above the substrate 102. In this example, the active electrical device 106 may include one or more transistors, such as metal-oxide-semiconductor field-effect transistors (MOSFETs). In aspects, although depicted as a planar transistor, the active electrical device 106 may include one or more multi-gate transistors, such as finFETs and/or GAA FETs. In certain aspects, the active electrical device 106 may be an inverter, amplifier, and/or other suitable electrical device comprising transistors. The local conductive contacts 110 may be electrically coupled to the active electrical device 106. For example, the gate, source, and/or drain of the active electrical device 106 may be electrically coupled to the local conductive contacts 110, which may be electrically coupled to the first layer of conductive traces 112. That is, the local conductive contacts 110 may serve as the ohmic contacts that electrically couple the various metal layers (e.g., M1) to the terminals of the active electrical device 106 (such as the source, drain, or gate).

In certain aspects, the active electrical device 106 (and the local conductive contacts 110) may be formed during a front-end-of-line (FEOL) fabrication process. In aspects, the local conductive contacts 110 may be formed using a SAC process during the FEOL process. As further described herein, a nonconductive liner (not shown) may be formed between at least one of the local conductive contacts 110 and a gate of the active electrical device 106. The nonconductive liner may provide additional electrical insulation between at least one of the local conductive contacts 110 and the gate of the active electrical device 106 such that nonconductive liner may enable a desirable SAC process margin and mitigate gate-to-contact shorts, as well as capacitive coupling.

The layers of conductive traces/vias 112, 114, 116 may be disposed above electrical components (e.g., the active electrical device 106) and formed during a back-end-of-line (BEOL) fabrication process of the semiconductor device 100. In aspects, the layers of conductive traces/vias 112, 114, 116 may be embedded in the dielectric layers 108. In certain cases, the dielectric layers 108 may comprise an oxide, such as silicon dioxide. The layers of conductive traces/vias 112, 114, 116 provide electrical routing between the active electrical device 106 and other electrical components (not shown), including, for example, capacitors, inductors, resistors, an integrated passive device, a power management integrated circuit (PMIC), a memory chip, etc.

In this example, the semiconductor device 100 may be a flip-chip ball grid array (FC-BGA) integrated circuit having multiple solder bumps 120 electrically coupled to the under-bump conductive pads 118. The solder bumps 120 may enable electrical coupling between the semiconductor device 100 and various other electrical devices or components, such as a package substrate, an interposer, a circuit board, etc. In certain cases, instead of solder bumps, the semiconductor device 100 may have conductive pillars (e.g., copper (Cu) pillars) that electrically couple the semiconductor device 100 to a package substrate, an interposer, or a circuit board, for example.

### Example Gate-to-Contact Short Prevention in a FinFET Structure

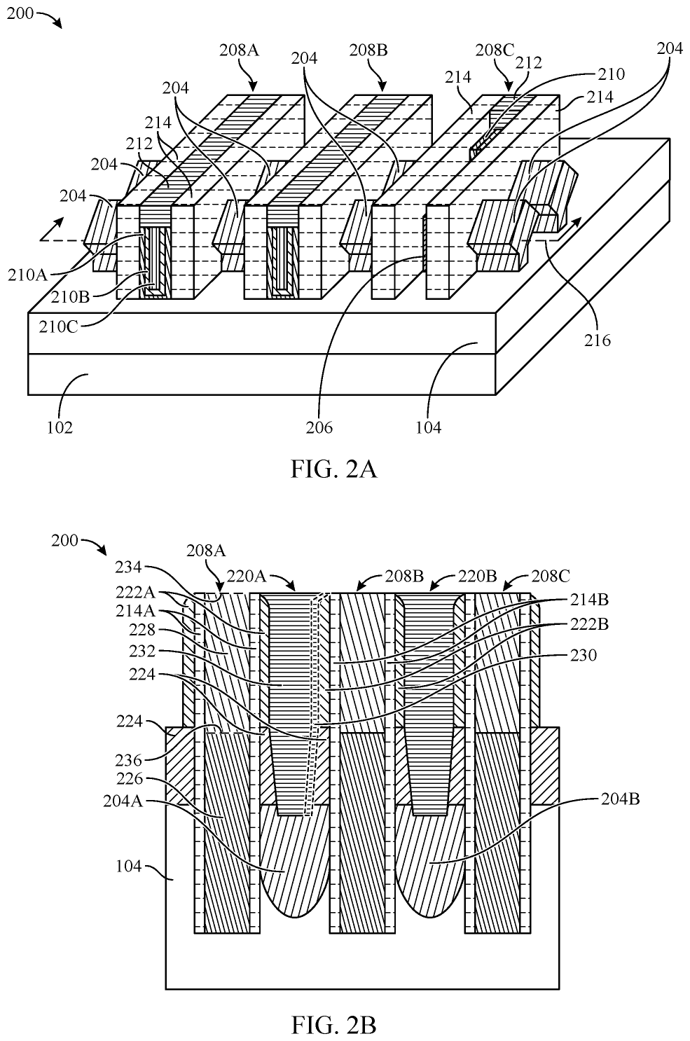

FIG. 2A is an isometric view illustrating an example finFET structure 200 disposed above the substrate 102, in accordance with certain aspects of the present disclosure. As shown, the finFET structure 200 may be formed above the substrate 102, and certain portions of the finFET structure 200 may be embedded in the dielectric region 104. The finFET structure 200 may include source/drain regions 204, channel regions 206, and gates 208A, 208B, 208C (collectively referred to as “gates 208”). Each of the source/drain regions 204 and channel regions 206 may be formed as a semiconductor fin that extends from the substrate 102 above the dielectric region 104. Each of the gates 208 may conform to the shape of the channel regions 206 (a portion of which is shown in the cut-out view of the third gate 208C), such that each of the gates 208 may engage or couple to multiple surfaces of the channel regions 206. For example, a portion of the gate 208A may be disposed between the channel regions 206 of adjacent fins, and other portions of the gate 208A may be disposed above the channel regions 206. That is, each of the gates 208 may partially surround each of the fins of the channel regions 206. Each of the channel regions 206 may be disposed between one of the source regions 204A and one of the drain regions 204B.

The source/drain regions 204 may include a doped (e.g., n+ or p+) semiconductor. In certain cases, the source/drain regions 204 may be epitaxially grown on the semiconductor fins adjacent to the areas of the fins designated for the channel regions 206. The fins (including the channel regions 206) may include a semiconductor, such as silicon (Si) or silicon germanium (SiGe). In certain aspects, the semiconductor of the channel regions 206 may be an n-type or p-type semiconductor, for example, via doping.

The gates 208 may include various layers of conductive materials and/or dielectric materials 210A-C. These gate layers may be collectively referred to as a “high-κ metal gate” 210. In certain cases, the conductive materials 210A, 210C of the gates 208 may include various work function metals including titanium nitride (TiN), aluminum (Al), tantalum nitride (TaN), titanium aluminide (TiAl), tungsten (W), etc. In aspects, the dielectric materials 210B of the gates 208 may include a high-κ dielectric. As used herein, a high-κ dielectric may include a dielectric material with a dielectric constant (κ) higher than silicon dioxide (SiO₂) (e.g., κ=3.9), such as hafnium dioxide (HfO₂), zirconium dioxide (ZrO₂), and/or titanium dioxide (TiO₂). The gates 208 may also include a dielectric cap 212 disposed above the high-κ metal gate 210. The dielectric cap 212 may be a SAC dielectric region, which provides an electrical insulator over the high-κ metal gate 210 during the source/drain SAC formation.

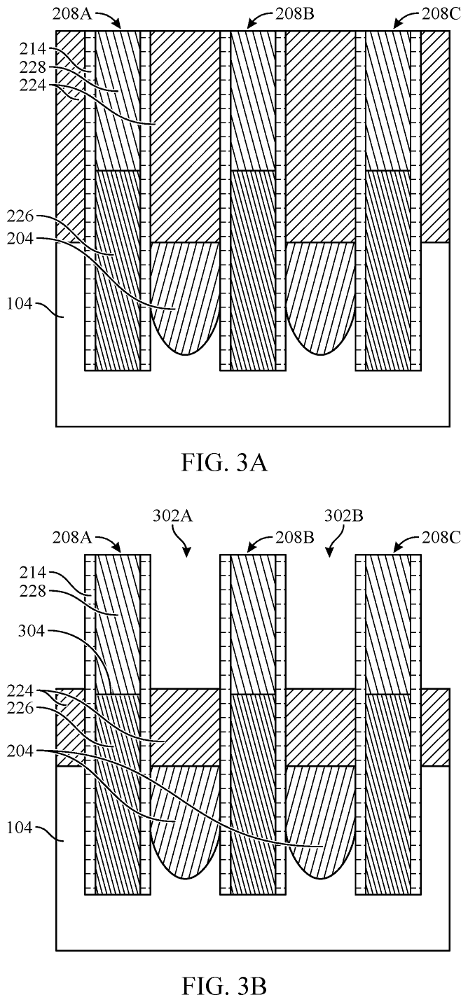

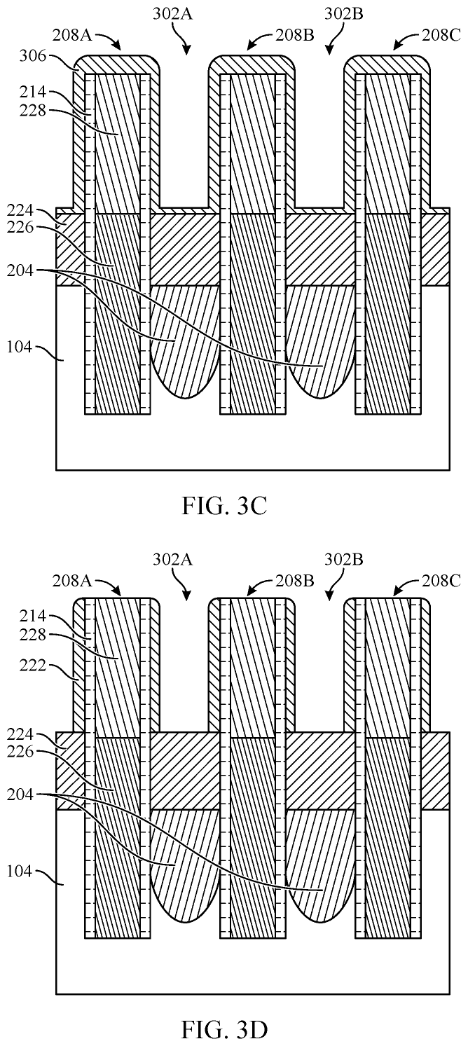

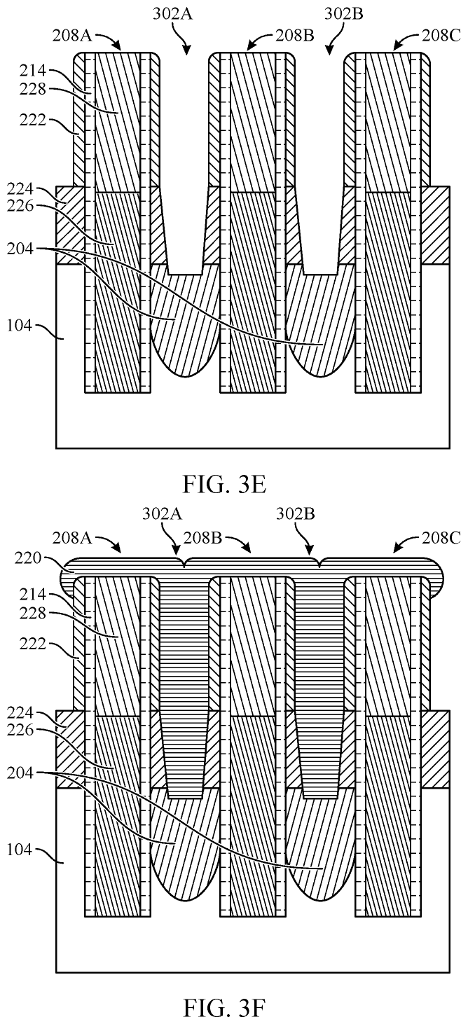

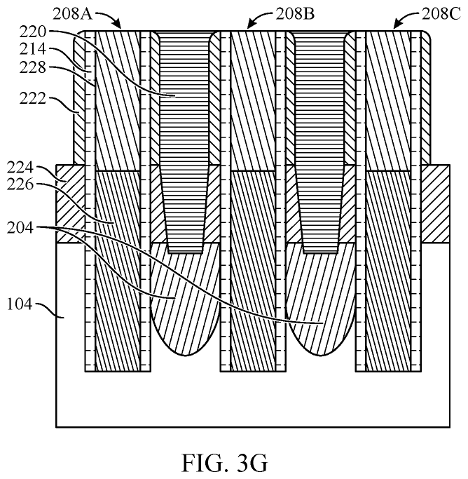

Gate spacers 214 may be disposed adjacent to opposite sides (e.g., opposite lateral surfaces) of the gates 208. The gate spacers 214 may include a dielectric material such as silicon dioxide and/or silicon nitride. As further described herein with respect to FIGS. 2B, 3A-G, and 4A-4F, the gate spacers 214 may be extended with a non-conductive liner.

Source/drain SACs may be formed above the source/drain regions 204, and the nonconductive liner may be formed between one of the gate spacers 214 and the source/drain SAC. The nonconductive liner may facilitate preventing or reducing a short (and/or decreasing capacitive coupling) between one of the gates and the source/drain SACs.

While this example is described herein with respect to a finFET structure having multiple gates and multiple fins with channel regions, source regions, and drain regions to facilitate understanding, aspects of the present disclosure may be applied to a finFET structure having a single fin that provides a channel region, a source region, and a drain region.

FIG. 2B is a cross-sectional view illustrating a portion of the example finFET structure 200 along the cross-section 216 as depicted in FIG. 2A. As shown, portions of the finFET structure 200 may be embedded in the dielectric region 104 (which may be referred to as the first dielectric region). In aspects, the cross-section 216 may be taken through the source/drain regions 204 in front of a lateral surface of one of the semiconductor fins. The finFET structure 200 may include a first source/drain region 204A, a first gate 208A, first gate spacers 214A, a first source/drain contact 220A, first nonconductive liners 222A, and a second dielectric region 224. In aspects, the finFET structure 200 may further include additional elements, such as the second source/drain region 204B, additional gates (e.g., the second gate 208B and third gate 208C), gate spacers (e.g., second gate spacers 214B), source/drain contacts (e.g., the second source/drain contact 220B), nonconductive liners (e.g., the second nonconductive liners 222B), etc. In aspects, the source/drain contacts described herein with respect to FIG. 2B may correspond to the local conductive contacts 110 depicted in FIG. 1.

As used herein, the first, second, and third gates 208A, 208B, 208C may be collectively referred to as the “gates 208”; the first and second gate spacers 214A, 214B may be collectively referred to as the “gate spacers 214”; the first and second source/drain contacts 220A, 220B may be collectively referred to as the “source/drain contacts 220”; and the first and second nonconductive liners 222A, 222B may be collectively referred to as the “nonconductive liners 222.”

The first gate 208A may be disposed above and partially surround a channel region (not shown in FIG. 2B) of the semiconductor fin. The first gate 208A may include a metal gate portion 226 (e.g., of the high-κ metal gate 210) and a self-aligned contact (SAC) dielectric region 228 (e.g., the dielectric cap 212) disposed above the metal gate portion. In certain aspects, the metal gate portion 226 of the first gate 208A may include a high-κ metal gate, for example, as described herein with respect to FIG. 2A. The SAC dielectric region 228 may include a dielectric material, such as a silicon nitride or silicon dioxide. In certain aspects, a SAC dielectric region that includes silicon nitride may be referred to as a “SAC nitride portion.” The SAC dielectric region 228 may serve as an electrically insulating material that covers the metal gate portion 226 during the formation of the SACs (such as the first source/drain contact 220A). For example, the SAC dielectric region 228 provides a layer of electrical insulation above the metal gate portion 226 in case there is a variation in the landing area of the SAC during the SAC formation process such that a portion of the SAC is formed directly above the metal gate portion 226. In other words, the SAC dielectric region 228 may compensate for variations in the positioning of the source/drain contacts during a SAC formation process and may reduce the development of a short or capacitive coupling between the metal gate portion 226 and the SAC across an upper region of the metal gate portion 226.

The first gate spacers 214A may be located adjacent to sides of the first gate 208A. For example, one of the first gate spacers 214A may be located adjacent to one of the sides of the first gate 208A, and the other first gate spacer 214A may be located adjacent to the opposite side of the first gate 208A. The first gate spacers 214A may extend from at least a top of the first gate 208A to a bottom of the first gate 208A. In aspects, the first gate spacers 214A may include a dielectric material, such as silicon dioxide or silicon nitride. The first gate spacers 214A may provide a layer of electrical insulation between the metal gate portion 226 and SACs (such as the first source/drain contact 220A). As further described herein, the layer of electrical insulation between the metal gate portion 226 and SACs may be extended by the first nonconductive liners 222A and/or the second dielectric region 224.

The first source/drain contact 220A may be coupled to the source/drain region 204A of the semiconductor fin. The first source/drain contact 220A may comprise a barrier metal layer 230 and a metal fill region 232 disposed above the barrier metal layer 230. For example, the barrier metal layer 230 may be disposed between the metal fill region 232 and the walls of a cavity (or trench) in which the first source/drain contact 220A is formed, such as the lateral surfaces of the first nonconductive liners 222A and the second dielectric region 224. Although the example in FIG. 2B only depicts a barrier metal layer on one side of the SAC to facilitate understanding, aspects of the present disclosure also apply to the barrier metal layer 230 covering the walls of the cavity (or trench) in which the SAC is formed.

The barrier metal layer 230 may provide a diffusion barrier to prevent or reduce diffusion of the metal fill region 232 into the walls of the cavity in which the first source/drain contact 220A is formed. In certain cases, the barrier metal layer 230 may include a metal (such as cobalt (Co), ruthenium (Ru), or tantalum (Ta)), a conductive ceramic (such as tantalum nitride, indium oxide, tungsten nitride, or titanium nitride), or a combination thereof. The metal fill region 232 may include an electrically conductive material, which may include various metals, metal alloys, or conductive ceramics including aluminum (Al), chromium (Cr), cobalt (Co), copper (Cu), gold (Au), molybdenum (Mo), platinum (Pt), tantalum (Ta), titanium (Ti), tungsten (W), etc.

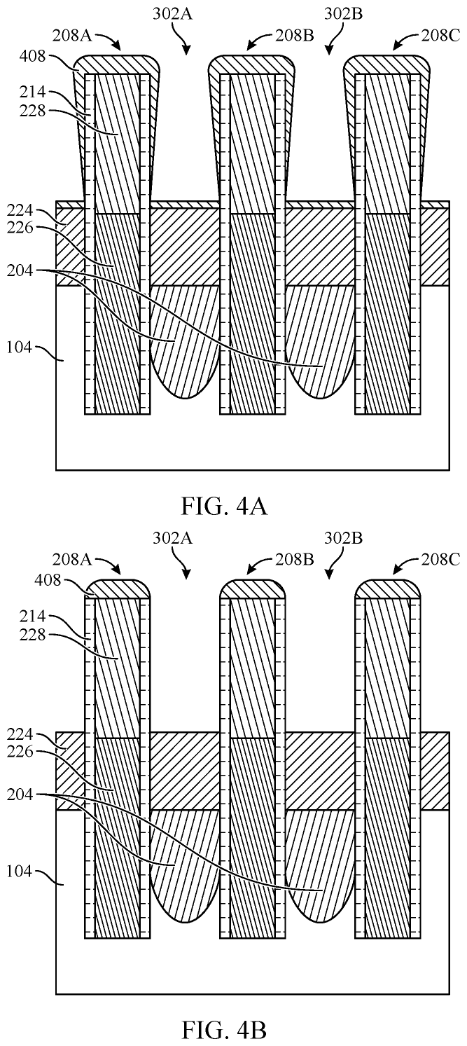

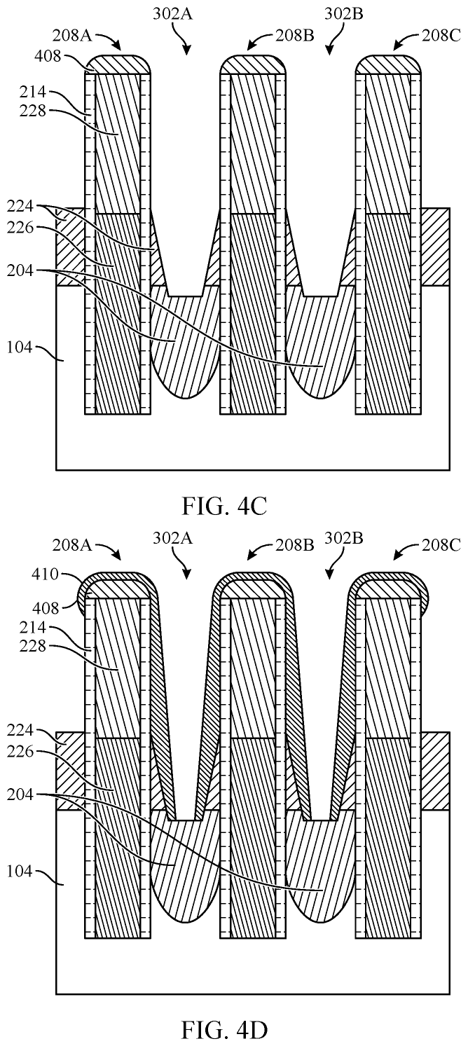

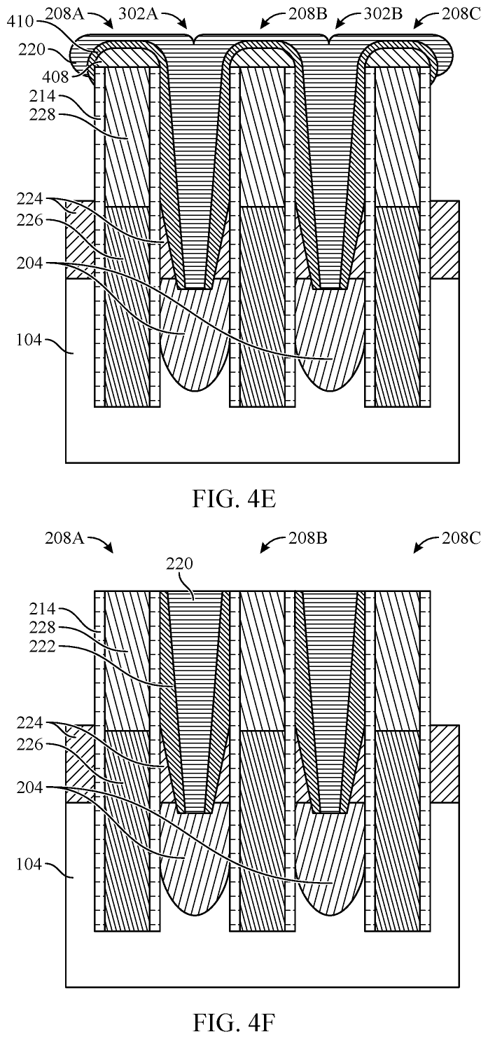

One of the first nonconductive liners 222A may be disposed between the first source/drain contact 220A and one of the first gate spacers 214A. In certain aspects, the first nonconductive liner 222A may cover a portion of the first spacer 214A and a lateral surface of the first source/drain contact 220A extending from a top 234 of the SAC dielectric region 228 to at least a bottom 236 of the SAC dielectric region 228. In certain aspects, the first nonconductive liner 222A may extend from the top 234 of the SAC dielectric region 228 to the semiconductor fin (e.g., to the top of the first source/drain region 204A), for example, as described herein with respect to FIG. 4F. The first nonconductive liner 222A may include silicon nitride or silicon dioxide. In general, the first nonconductive liner 222A may comprise a dielectric material, such as a nitride material, an oxide material, or a combination thereof. The first nonconductive liner 222A may extend the electrical insulation between the metal gate portion 226 of the first gate 208A and the first source/drain contact 220A. In other words, the first nonconductive liner 222A may provide a layer of electrical insulation in addition to one of the first gate spacers 214A between the metal gate portion 226 of the first gate 208A and the first source/drain contact 220A. The first nonconductive liner 222A may prevent or reduce a short (and/or capacitive coupling) between the metal gate portion 226 of the first gate 208A and the first source/drain contact 220A, for example, during the SAC formation process, as further described herein with respect to FIGS. 3A-3G and 4A-4F.

The second dielectric region 224 may be disposed below the first nonconductive liner 222A and disposed between the first source/drain contact 220A and the first spacer 214A. In aspects, the second dielectric region 224 may be disposed above the first source/drain region 204A. The second dielectric region 224 may serve as an interlayer dielectric (ILD) for the SACs. That is, the second dielectric region 224 may provide electrical insulation between the SACs. The second dielectric region 224 may include a dielectric material such as silicon dioxide or silicon nitride. The second dielectric region 224 may extend the electrical insulation between the metal gate portion 226 of the first gate 208A and the first source/drain contact 220A. That is, the second dielectric region 224 may provide a layer of electrical insulation in addition to one of the first gate spacers 214A between the metal gate portion 226 of the first gate 208A and the first source/drain contact 220A. The second dielectric region 224 may prevent or reduce a short (and/or capacitive coupling) between the metal gate portion 226 of the first gate 208A and the first source/drain contact 220A, for example, during the SAC formation process, as further described herein with respect to FIGS. 3A-3G and 4A-4F.

In certain aspects, the second gate 208B may be disposed above and partially surround another channel region (not shown in FIG. 2B) of the semiconductor fin. The first source/drain region 204A of the semiconductor fin may be disposed between the first and second gates 208A, 208B.

Second gate spacers 214B may be located adjacent to sides of the second gate 208B, for example, as described herein with respect to the first gate spacers 214A. As an example, one of the second gate spacers 214B may be located adjacent to one of the sides of the second gate 208B, and the other second gate spacer 214B may be located adjacent to the opposite side of the second gate 208B. One of the second nonconductive liners 222B may be disposed between the first source/drain contact 220A and one of the second gate spacers 214B, for example, as described herein with respect to the first nonconductive liners 222A.

FIGS. 3A-3G are cross-sectional views illustrating example operations for fabricating a finFET structure (e.g., the finFET structure 200) with nonconductive liners disposed between the source/drain contacts and the gate spacers, in accordance with certain aspects of the present disclosure. In aspects, FIGS. 3A-3G depict the cross-sections along the cross-section 216 as depicted in FIG. 2A. The operations for fabricating the finFET structure may be performed by a semiconductor fabrication facility, for example. The operations may include various front-end-of-line (FEOL) fabrication processes, when active electrical devices (e.g., the finFET structure 200) are patterned and formed on a substrate (e.g., the substrate 102). Various back-end-of-line (BEOL) fabrication processes may be performed after the operations described herein with respect to FIGS. 3A-3G. The BEOL fabrication processes may refer to when the various electrical devices are electrically interconnected with conductive layers (e.g., M1, M2, and M3) and conductive vias, and when passive electrical devices may be formed above the active electrical devices.

As shown in FIG. 3A, after formation of the various transistor regions (such as the channel regions, source/drain regions, and gates), the second dielectric region 224 may be formed between the gate spacers 214 associated with the gates 208 (such as the first gate 208A, the second gate 208B, and the third gate 208C). In aspects, after the replacement metal gate (RMG) process is performed and the SAC dielectric region 228 is formed above the metal gate portions 226, the second dielectric region 224 may be formed above the source/drain regions 204 of the semiconductor fin. A hard mask (not shown) may be used to selectively pattern the SAC dielectric region 228, and a planarization process may be used to remove that hard mask and smooth/level the top surface of the gates 208. This hard mask may be referred to as a post-SAC hard mask. As used herein, the RMG process may refer to the process of forming the metal gate portions using a dummy gate and dummy gate dielectric to serve as temporary molds for the metal and dielectric layers of the gate. A planarization process (e.g., a chemical mechanical planarization (CMP) process) may be performed to smooth and level the upper surface of the gates 208 and second dielectric region 224. In aspects, the planarization process may also remove the hard mask used to selectively pattern the SAC dielectric regions 228.

Referring to FIG. 3B, a portion of the second dielectric region 224 may be removed above the source/drain regions 204. For example, cavities 302A, 302B may be formed in the second dielectric region 224 above the source/drain regions 204 of the semiconductor fin. In certain aspects, a bottom depth of the cavities 302A, 302B may stop at or near the top 304 of the metal gate portions 226. An etching process (e.g., a wet etching process and/or dry etching process) may be used to selectively remove portions of the second dielectric region 224 and form the cavities 302A, 302B.

As depicted in FIG. 3C, a dielectric layer 306 may be formed over the gates 208, the gate spacers 214, and the second dielectric region 224. The dielectric layer 306 may be a conformal layer. In aspects, the dielectric layer 306 may be formed on the side walls of the cavities 302A, 302B (such as a portion of the gate spacers 214) and above the gates 208. The dielectric layer 306 may be referred to as a “spacer liner” because the dielectric layer 306 may cover at least a portion of the gate spacers 214. The dielectric layer 306 may include a dielectric material, such as silicon dioxide or silicon nitride.

Referring to FIG. 3D, portions of the dielectric layer 306 may be removed to allow for contact with the gates 208 and for extension of the cavities 302A, 302B, as further described herein with respect to FIG. 3E. For example, the portions of the dielectric layer 306 disposed above the tops of the gates 208 may be removed, and the portions of the dielectric layer 306 engaged with the second dielectric region 224 may be removed. An etching process may be used to selectively remove portions of the dielectric layer 306. The remaining portions of the dielectric layer 306 may serve as the nonconductive liner 222 that extends the electrical insulation between the metal gate portions 226 and the SACs, such that the dielectric layer 306 may prevent or reduce shorting (and/or capacitive coupling) between the metal gate portions 226 and the SACs.

As illustrated in FIG. 3E, the cavities 302A, 302B may be extended to intersect the remaining second dielectric region 224 above the source/drain regions 204 and expose a surface of the semiconductor fin. That is, the portions of the second dielectric region 224 may be removed above the semiconductor fin, such that the upper surfaces of the source/drain regions 204 are exposed for SAC formation. The cavities 302A, 302B may serve as the molds for the SACs. An etching process may be used to selectively remove portions of the second dielectric region 224. During the selective removal process of the second dielectric region 224, the nonconductive liner 222 (e.g., the remaining portions of the dielectric layer 306) may prevent or reduce erosion of portions of the gate spacers 214, such as the portion of the gate spacers 214 extending the length of the nonconductive liner 222 in the cavities 302A, 302B.

Referring to FIG. 3F, the source/drain contacts 220 may be formed (e.g., deposited) in the cavities 302A, 302B. For example, a barrier metal (e.g., the barrier metal layer 230) may first be formed in the cavities 302A, 302B (e.g., to line the walls of the cavities), and then another metal (e.g., the metal fill region 232) may be formed over the barrier metal in the cavities 302A, 302B.

As shown in FIG. 3G, a planarization process (e.g., a CMP process) may be performed to smooth and level the upper surfaces of the source/drain contacts 220. In aspects, the planarization process may also remove portions of the contacts 220 disposed above the gates 208.

In certain aspects, a hard mask may be used to reduce erosion of gate spacers, and the nonconductive liner may extend the depth of the cavities in which the SACs are formed. For example, FIGS. 4A-4F are cross-sectional views illustrating example operations for fabricating a finFET structure with a hard mask and a nonconductive liner extending the depth of the cavities, in accordance with certain aspects of the present disclosure. In aspects, FIGS. 4A-4F depict the cross-sections along the cross-section 216 as depicted in FIG. 2A. The operations for fabricating the finFET structure may be performed by a semiconductor fabrication facility, for example. The operations may include various FEOL fabrication processes. In aspects, the operations depicted in FIGS. 4A-4F may begin after the operations depicted in FIGS. 3A and 3B are completed. That is, the operations depicted in FIGS. 4A-4F may begin after forming the cavities 302A, 302B in the second dielectric region 224.

As shown in FIG. 4A, a hard mask layer 408 may be formed above the gates 208, gate spacers 214, and the second dielectric region 224. In aspects, the hard mask layer 408 may be formed on the side walls of the cavities 302A, 302B (such as a portion of the gate spacers 214) and above the gates 208. The hard mask layer 408 may be formed using a physical vapor deposition (PVD) process, for example. In aspects, the hard mask layer 408 may include a metallic material resistant to the etching process used to extend the cavities 302A, 302B as further described herein with respect to FIG. 4C.

Referring to FIG. 4B, portions of the hard mask layer 408 may be removed. For example, portions of the hard mask layer 408 deposited in the cavities 302A, 302B may be removed, such that the remaining portions of the hard mask layer 408 are disposed above the gates 208 and gate spacers 214, but not in the cavities 302A, 302B and not above the second dielectric region 224. In aspects, the hard mask layer 408 may prevent or reduce the erosion of the gate spacers 214 during the further etching performed to extend the cavities 302A, 302B, for example, as described herein with respect to FIG. 4C. An etching process may be used to selectively remove portions of the hard mask layer 408.

As depicted in FIG. 4C, the cavities 302A, 302B may be extended to intersect the remaining second dielectric region 224 above the semiconductor fin and expose surfaces of the source/drain regions 204 between the gates 208. In aspects, because the hard mask layer 408 is disposed above the gate spacers 214, the hard mask layer 408 may serve as a protective cover over the gate spacers 214 to prevent at least some etchant from eroding portions of the gate spacers 214 and/or the second dielectric region 224. An etching process may be used to selectively remove portions of second dielectric region 224.

Referring to FIG. 4D, a dielectric layer 410 may be formed over the gates 208, the remaining portions of the hard mask layer 408, the gate spacers 214, and the second dielectric region 224. The dielectric layer 410 may be referred to as a “spacer liner.” The dielectric layer 410 may be a conformal layer. In aspects, the dielectric layer 410 may be formed on the side walls of the cavities 302A, 302B (such as a portion of the gate spacers 214 and a portion of the second dielectric region 224) and above the remaining portions of the hard mask layer 408. The dielectric layer 410 may include a dielectric material, such as silicon dioxide or silicon nitride. Portions of the dielectric layer 410 may be removed to enable the exposure of the source/drain regions 204 in the cavities 302A, 302B and formation of the SACs, as further described herein with respect to FIG. 4E. An etching process may be used to selectively remove portions of the dielectric layer 410. The remaining portions of the dielectric layer 410 (and the second dielectric region 224) in the cavities 302A, 302B may serve as the nonconductive liner that extends the electrical insulation of the gate spacers 214 between the metal gate portions 226 and the SACs. In aspects, the remaining portions of the dielectric layer 410 may fill in some erosion of the gate spacers 214 due to the cavities 302A, 302B being formed or extended. The dielectric layer 410 may also facilitate preventing or reducing a short (and/or decreasing capacitive coupling) between the metal gate portion 226 and the SACs.

As illustrated in FIG. 4E, the source/drain contacts 220 may be formed (e.g., deposited) in the cavities 302A, 302B. For example, a barrier metal (e.g., the barrier metal layer 230) may first be formed in the cavities 302A, 302B (e.g., to line the walls of the cavities), and then another metal (e.g., the metal fill region 232) may be formed over the barrier metal in the cavities 302A, 302B.

Referring to FIG. 4F, a planarization process (e.g., a CMP process) may be performed to smooth and level the upper surfaces of the source/drain contacts 220. In aspects, the planarization process may also remove portions of the contacts 220, the dielectric layer 410, and the hard mask layer 408 disposed above the gates 208.

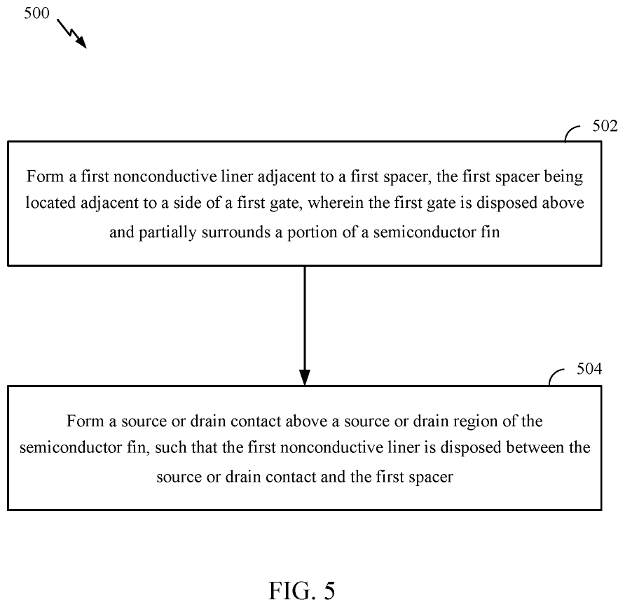

FIG. 5 is a block diagram illustrating example operations 500 for fabricating a finFET structure (e.g., the finFET structure 200 depicted in FIG. 2B), in accordance with certain aspects of the present disclosure. The operations may be performed by a semiconductor fabrication facility or a foundry, for example.

The operations 500 may begin at block 502, where a first nonconductive liner (e.g., the first nonconductive liner 222A) may be formed adjacent to a first spacer (e.g., the first gate spacer 214A). The first spacer may be located adjacent to a side of a first gate (e.g., the first gate 208A), where the first gate may be disposed above and partially surround a portion of a semiconductor fin (e.g., a channel region 206 of the fin). At block 504, a source or drain contact (e.g., the first source/drain contact 220A) may be formed above a source or drain region (e.g., the first source/drain region 204) of the semiconductor fin, such that the first nonconductive liner is disposed between the source or drain contact and the first spacer.

In certain aspects, a second nonconductive liner (e.g., the second nonconductive liner 222B) may be formed adjacent to a second spacer (e.g., the second gate spacer 214B), where the second spacer may be located adjacent to a side of a second gate (e.g., the second gate 208B). The second gate may be disposed above and partially surround another portion (e.g., another channel region) of the semiconductor fin. The first gate and the second gate may be disposed on opposite sides of the source or drain region. The source or drain contact may be formed such that the second nonconductive liner is disposed between the source or drain contact and the second spacer. In aspects, the first nonconductive liner may prevent or reduce shorting (and/or capacitive coupling) between a metal gate portion (e.g., the metal gate portion 226) of the first gate and the source or drain contact, and the second nonconductive liner may prevent or reduce shorting (and/or capacitive coupling) between a metal gate portion of the second gate and the source or drain contact.

In aspects, the formation of the first and second nonconductive liner may be formed using the same deposition and etching processes. That is, the formation of the first and second nonconductive liners may be performed at block 502, for example, as described herein with respect to FIGS. 3C-3D or FIG. 4D. In certain cases, formation of the first nonconductive liner and the second nonconductive liner may include depositing a spacer liner (e.g., the dielectric layer 306 or 410) above the first gate, the first spacer, the second gate, the second spacer, and a dielectric region (e.g., the second dielectric region 224) disposed above the source or drain region and between the first and second spacers. For example, the spacer liner may be formed as described herein with respect to FIG. 3C or FIG. 4D. Portions of the spacer liner may be removed above the first gate, above the second gate, and above the dielectric region, such that remaining portions of the spacer liner include the first nonconductive liner disposed adjacent to the first spacer and the second nonconductive liner disposed adjacent to the second spacer. For example, portions of the spacer liner may be removed using an etching process and/or a planarization process as described herein with respect to FIG. 3D or FIG. 4F.

In aspects, formation of the source or drain contact at block 504 may include removing at least a portion of the dielectric region to form a trench (e.g., the cavity 302A) extending down to the source or drain region, for example, as described herein with respect to FIG. 3E or FIG. 4C. Removal of a portion of the dielectric region (e.g., the second dielectric region 224) may leave a first remaining dielectric region disposed below the first nonconductive liner and disposed between the source or drain contact and the first spacer. Removal of a portion of the dielectric region may also leave a second remaining dielectric region disposed below the second nonconductive liner and disposed between the source or drain contact and the second spacer, for example, as described herein with respect FIG. 3E. At least one metal (e.g., the barrier metal layer 230 and/or the metal fill region 232) may be deposited in the trench and above at least one of the first gate or the second gate, for example, as described herein with respect to FIG. 3F or FIG. 4E. The deposited metal may be planarized to be even with a top of the first gate and a top of the second gate, for example, as described herein with respect to FIG. 3G or FIG. 4F. The deposition of the metal of the source or drain contact may include depositing a barrier metal layer in the trench and above at least one of the first gate or the second gate and depositing a metal fill region above the barrier metal layer.

In certain aspects, a hard mask may be formed to further protect against erosion of the gate spacers while etching away the dielectric region above the semiconductor fins, for example, as described herein with respect to FIGS. 4A and 4B. As an example, formation of the first nonconductive liner and the second nonconductive liner may include forming a first hard mask above the first gate and forming a second hard mask above the second gate. In aspects, the first hard mask and second hard mask may be formed through formation of a hard mask layer 408 above the gates 208, for example, as described herein with respect to FIGS. 4A and 4B. At least a portion of the dielectric region (e.g., the second dielectric region 224) may be removed above the source or drain region and between the first and second spacers to form a trench (e.g., the cavity 302A as depicted in FIG. 4C) extending down to the source or drain region, for example, as described herein with respect to FIGS. 4B and 4C. The hard masks above the gates may protect the gate spacers from eroding during the etching process to remove the dielectric region above the semiconductor fin. A nonconductive liner (e.g., the dielectric layer 410) may be formed above the first hard mask, the first spacer, the second hard mask, the second spacer, and the source or drain region. A portion of the nonconductive liner may be removed above the source or drain region, such that remaining portions of the nonconductive liner include the first nonconductive liner disposed adjacent to the first spacer and the second nonconductive liner disposed adjacent to the second spacer, for example, as described herein with respect to FIG. 4D.

Formation of the source or drain contact may include depositing at least one metal in the trench and above at least one of the first gate or the second gate and planarizing the deposited metal even with a top of the first gate and a top of the second gate, for example, as described herein with respect to FIGS. 4E and 4F. The planarization may remove the first hard mask, the second hard mask, and portions of the nonconductive liner above the first and second hard masks.

While various examples provided herein are described with respect to a finFET structure to facilitate understanding, aspects of the present disclosure may be applied to other source/drain SAC processes, such as the SAC processes of planar or multi-gate FETs (e.g., GAA FETs).

It should be appreciated that the SAC formation techniques and the nonconductive liner described herein provide various advantages. For example, aspects of the SAC formation techniques may prevent or reduce erosion of the gate spacers during certain etching processes, such as the etching process used to form the cavities in which the SACs are formed. The nonconductive liner described herein may prevent or reduce shorting (and/or capacitive coupling) between a metal gate and a source/drain SAC, which may provide desirable transistor yields in various semiconductor devices.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes, and variations may be made in the arrangement, operation, and details of the methods and apparatus described above without departing from the scope of the claims.

1. A fin field-effect transistor (finFET) structure comprising:
a semiconductor fin;
a first gate disposed above and partially surrounding a portion of the semiconductor fin;
a first spacer located adjacent to a side of the first gate;
a source or drain contact coupled to a source or drain region of the semiconductor fin; and
a first nonconductive liner disposed between the source or drain contact and the first spacer.

2. The finFET structure of claim 1, further comprising:
a second gate disposed above and partially surrounding another portion of the semiconductor fin, wherein the first gate and the second gate are disposed on opposite sides of the source or drain region;
a second spacer located adjacent to a side of the second gate; and
a second nonconductive liner disposed between the source or drain contact and the second spacer.

3. The finFET structure of claim 1, further comprising:
a second spacer located adjacent to another side of the first gate; and
a second nonconductive liner disposed adjacent to the second spacer.

4. The finFET structure of claim 1, wherein the first nonconductive liner comprises a nitride material.

5. The finFET structure of claim 1, wherein the first nonconductive liner comprises an oxide material.

6. The finFET structure of claim 1, wherein:
the first gate comprises a metal gate portion and a self-aligned contact nitride portion disposed above the metal gate portion; and
the first nonconductive liner covers a portion of the first spacer extending from a top of the self-aligned contact nitride portion to at least a bottom of the self-aligned contact nitride portion.

7. The finFET structure of claim 1, wherein the source or drain contact comprises a barrier metal layer and a metal fill region disposed above the barrier metal layer.

8. The finFET structure of claim 1, further comprising a dielectric region disposed below the first nonconductive liner and disposed between the source or drain contact and the first spacer.

9. The finFET structure of claim 1, wherein the first nonconductive liner covers a lateral surface of the source or drain contact, extending from a top of the source or drain contact to a bottom of the source or drain contact.

10. The finFET structure of claim 1, wherein the first gate comprises a high-κ metal gate.

11. A method of fabricating a fin field-effect transistor (finFET) structure, the method comprising:
forming a first nonconductive liner adjacent to a first spacer, the first spacer being located adjacent to a side of a first gate, wherein the first gate is disposed above and partially surrounds a portion of a semiconductor fin; and
forming a source or drain contact above a source or drain region of the semiconductor fin, such that the first nonconductive liner is disposed between the source or drain contact and the first spacer.

12. The method of claim 11, further comprising forming a second nonconductive liner adjacent to a second spacer, the second spacer being located adjacent to a side of a second gate, wherein:
the second gate is disposed above and partially surrounds another portion of the semiconductor fin;
the first gate and the second gate are disposed on opposite sides of the source or drain region; and
the source or drain contact is formed such that the second nonconductive liner is disposed between the source or drain contact and the second spacer.

13. The method of claim 12, wherein forming the first nonconductive liner and forming the second nonconductive liner comprise:
depositing a spacer liner above the first gate, the first spacer, the second gate, the second spacer, and a dielectric region disposed above the source or drain region and between the first and second spacers; and
removing portions of the spacer liner above the first gate, above the second gate, and above the dielectric region, such that remaining portions of the spacer liner include the first nonconductive liner disposed adjacent to the first spacer and the second nonconductive liner disposed adjacent to the second spacer.

14. The method of claim 13, wherein:
the first gate comprises a metal gate portion and a self-aligned contact nitride portion disposed above the metal gate portion;
the first nonconductive liner covers a portion of the first spacer extending from a top of the self-aligned contact nitride portion of the first gate to at least a bottom of the self-aligned contact nitride portion of the first gate;
the second gate comprises a metal gate portion and a self-aligned contact nitride portion disposed above the metal gate portion; and
the second nonconductive liner covers a portion of the second spacer extending from a top of the self-aligned contact nitride portion of the second gate to at least a bottom of the self-aligned contact nitride portion of the second gate.

15. The method of claim 13, wherein forming the source or drain contact comprises:
removing at least a portion of the dielectric region to form a trench extending down to the source or drain region;
depositing at least one metal in the trench and above at least one of the first gate or the second gate; and
planarizing the deposited metal even with a top of the first gate and a top of the second gate.

16. The method of claim 15, wherein removing the at least the portion of the dielectric region leaves:
a first remaining dielectric region disposed below the first nonconductive liner and disposed between the source or drain contact and the first spacer; and
a second remaining dielectric region disposed below the second nonconductive liner and disposed between the source or drain contact and the second spacer.

17. The method of claim 15, wherein depositing the at least one metal comprises:
depositing a barrier metal layer in the trench and above at least one of the first gate or the second gate; and
depositing a metal fill region above the barrier metal layer.

18. The method of claim 12, wherein forming the first nonconductive liner and forming the second nonconductive liner comprise:
forming a first hard mask above the first gate;
forming a second hard mask above the second gate;
removing at least a portion of a dielectric region disposed above the source or drain region and between the first and second spacers to form a trench extending down to the source or drain region;
depositing a nonconductive liner above the first hard mask, the first spacer, the second hard mask, the second spacer, and the source or drain region; and
removing a portion of the nonconductive liner above the source or drain region, such that remaining portions of the nonconductive liner include the first nonconductive liner disposed adjacent to the first spacer and the second nonconductive liner disposed adjacent to the second spacer.

19. The method of claim 18, wherein forming the source or drain contact comprises:
depositing at least one metal in the trench and above at least one of the first gate or the second gate; and
planarizing the deposited metal even with a top of the first gate and a top of the second gate, wherein the planarizing removes the first hard mask, the second hard mask, and portions of the nonconductive liner above the first and second hard masks.

20. The method of claim 11, wherein the first nonconductive liner comprises a nitride material.
